(19) United States
(12) Patent Application Publication
(10) Pub. No.: US 2008/0003803 A1
(43) Pub. Date: Jan. 3, 2008

(54) Semiconductor package substrate for flip chip packaging

(76) Inventors: Pei-Haw Tsao, Taichung (TW); Pao-Kang Niu, Hsinchu (TW); D. J. Perng, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(21) Appl. No.: 11/477,933

(22) Filed: Jun. 30, 2006

(51) Int. Cl. H01L 21/44; H01L 27/082; H01L 27/102

(52) U.S. Cl. 438/613; 257/E23.021; 257/587

(57) ABSTRACT

A method for forming a semiconductor package is provided. In one embodiment, the method comprises providing a semiconductor substrate having at least one bump pad formed thereon. A solder mask layer is provided above the bump pad, the solder mask layer having at least one opening formed therein exposing a portion of the bump pad. A layer of solder wettable material is formed on the exposed surface of the bump pad and the sidewalls and substantially on the comers of the solder mask layer. A solder material is deposited above the layer of solder wettable material and portions of the solder mask layer and the solder material is reflown to create a solder bump.

### BACKGROUND

The present invention relates generally to flip chip packaging technology, and more particularly, to substrate structures for flip chip packaging.

Flip chip packaging is an advanced type of integrated circuit packaging technology that allows the overall package size to be made very compact. By flip chip packaging, a semiconductor chip is mounted in an upside-down manner over a substrate formed with an array of bump pads, and which is mechanically bonded and electrically coupled to the substrate by means of solder bumps. As device features continue to scale down, fine pitch substrate pad designs are often employed in flip chip packaging.

A typical fine pitch substrate pad design called a SMD (Solder Mask Design) is shown in FIG. 1. The substrate pad configuration comprises a substrate 108, which is provided with an array of bump pads 106 (only one bump pad is shown in FIG. 1) and may be provided with one or more conductive layers 110 sandwiched between dielectric layers 107 of substrate 108. A solder mask layer 104 is formed over substrate 108 and has an opening therein exposing a portion of bump pad 106. A solder material 102 is then formed over the solder mask layer opening.

FIG. 2 is a cross-sectional view of the flip chip package of FIG. 1 showing a subsequent processing step in which the solder material 102 is reflown to create a solder bump 103, which is formed on the active surface 101 of chip 100 to electrically contact substrate 108 to chip 100. In theory, surface tension effects will cause the solder material to ball-up during the reflow process to form a ball confined to the bond pad. In practice, however, what typically happens is that the mechanical integrity of the solder bump joint can be compromised. Cavity 112 formed at the joint of solder bump 103 and solder mask layer 104 and solder bump joint crack 111 typically develop after the reflow process. These defects form as a result of the non-wetting contact of solder material 102 and solder mask layer 104 and insufficient solder material volume in fine pitch substrate processing. Also produced in the conventional processing are solder bump area reduction and excessive solder flux residues. Unfortunately, these defects often lead to IC package failure during its service life or during reliability testing.

In view of these and other deficiencies in conventional methods for fabrication flip chip packages, improvements in substrates, and in fabrication methods for flip chip packages, are needed in the art.

### SUMMARY

The present invention is directed to a method for forming a semiconductor package is provided. In one embodiment, the method comprises providing a semiconductor substrate having at least one bump pad formed thereon. A solder mask layer is provided above the bump pad, the solder mask layer having at least one opening formed therein exposing a portion of the bump pad. A layer of solder wettable material is formed on the exposed surface of the bump pad and the sidewalls and substantially on the comers of the solder mask layer. A solder material is deposited above the layer of solder wettable material and portions of the solder mask layer and the solder material is reflown to create a solder bump.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a conventional flip chip substrate showing deposition of a solder material thereover.

FIG. 2 is a cross-sectional view of the flip chip substrate of FIG. 1 showing a subsequent processing step in which the solder material is reflown to create a solder bump.

FIG. 3 is a cross-sectional view of a flip chip substrate showing formation of a solder wettable layer and deposition of a solder material over the substrate according to one aspect of the present invention.

FIG. 4 is a cross-sectional view of the flip chip substrate of FIG. 3 showing a subsequent processing step according to one aspect of the present invention.

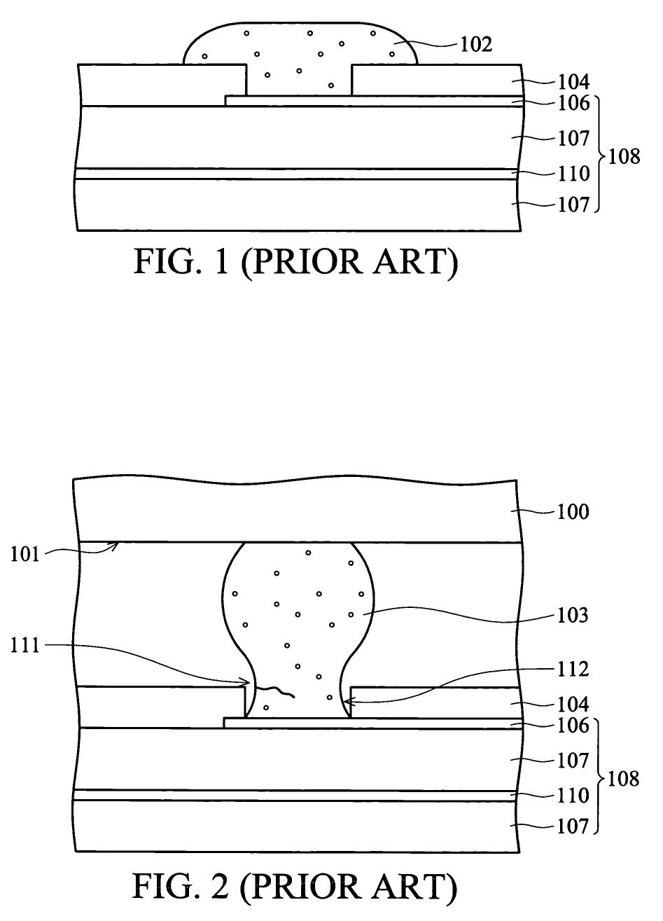

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present embodiments of the invention, examples of which are illustrated in the accompanying drawings.

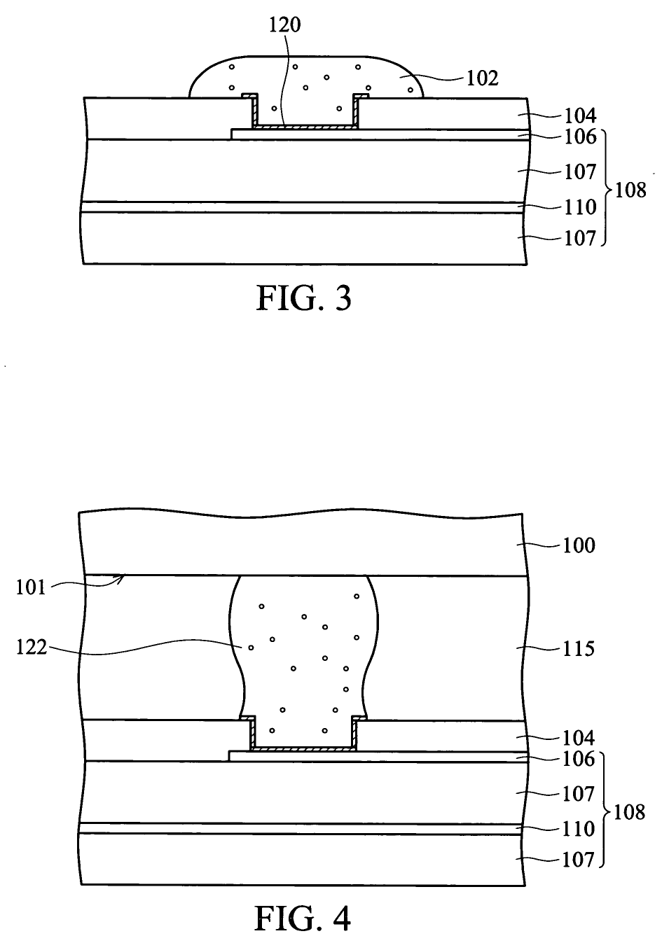

FIG. 3 is a cross-sectional view of a semi-finished flip chip substrate according to one embodiment of the present invention. The flip chip substrate comprises substrate 108, which is provided with an array of bump pads 106 (only one bump pad is shown in FIG. 3) and may be provided with one or more conductive layers 110 sandwiched between dielectric layers 107 of substrate 108. A solder mask layer 104 is formed over substrate 108 and has an opening therein exposing a portion of bump pad 106. Substrate 108 may comprise of SMD (solder mask define) bump pad design, plastic substrates or ceramic substrates, for example, and in general, an organic type substrate is preferable for lower cost and superior dielectric property whereas an inorganic type substrate is preferable when high thermal dissipation and matched coefficient of thermal expansion is desired. It is understood that the type of the substrate is a design choice dependent on the fabrication process being employed. Substrate 108 may have at least one or more conductive layers 110 sandwiched between dielectric layer 107. As is understood by those skilled in the art, conductive layers 110 may function as signal, power, and/or ground layers and may include silicon oxide, silicon nitride, silicon oxynitride, low-k dielectric materials, high-k dielectric materials, or combinations thereof. Bump pad 106 comprises a conductive material such as, for example copper or aluminum and is formed by conventional photolithographic and etching processes.

A solder mask layer 104 is formed over substrate 108 and has an opening therein exposing a portion of bump pad 106. The material for forming solder mask layer 104 comprises a solder resistant material that may include ultraviolet type of solder mask and thermoset type of solder mask and the method for forming solder mask layer 104 may include, for example roller coating, curtain coating, screen curtain, dipping, and dry film, as is understood by those skilled in the art.

To allow for better bonding and wetting of a subsequently deposited solder material to the bump pad 106 and increase the bump pad area adhesion strength and stability thereby avoiding the occurrence of solder bump cracks and cavities, one important aspect of the present invention is the addition of a step of depositing a layer 120 of solder wettable material on the exposed surface of the bump pad 106 and the sidewalls and substantially the corners of the solder mask layer 104. Layer 120 is a solder wettable material and may comprise of copper (Cu), nickel (Ni), palladium (Pd), cobalt (Co), platinum (Pt), ruthenium (Ru), tin (Sn), silver (Ag), gold (Au), and combinations thereof. In one embodiment, layer 120 comprises of a Cu/Ni alloy. In another embodiment, layer 120 comprises of a Ni/Au alloy. Deposition techniques such as plating, electroless-plating, and sputtering may be used to deposit layer 120 on substrate 108. It is understood by those of ordinary skill in the art that alternative techniques may be used for applying layer 120. Layer 120 may comprise of a single layer or a multi-layer and in one embodiment, layer 120 has a thickness in the range of about 0.1 μm to about 15 μm. A solder material 102 is then formed over layer 120 and portions of the solder mask layer 104.

FIG. 4 is a cross-sectional view of the flip-chip substrate of FIG. 3 showing a subsequent processing step in which solder material 102 is reflown to create a solder bump 122, which is formed on the active surface 101 of chip 100 to electrically contact substrate 108 to chip 100. During the reflow process, the layer 120 of solder wettable material reacts with solder material 102 causing solder bump 122 to become securely attached to bump pad 106. The solder reflow process causes at least some of the wettable material in layer 120 to dissolve into solder bump 122. As a result, there is a gradient associated with the transition from the solder wettable material to solder as one moves from the bump pad 106 through the solder bump 122. Because solder bump 122 adheres substantially to layer 120, solder bump 122 does not exhibit the cracks and/or cavities as exist in the conventional fine pitch substrate processing.

The strong, reliable solder bump joint to the solder mask layer 104 achieved with the use of layer 120 of solder wettable material provides flip chip packages with robust, higher densities and more reliable interconnections. An underfill material 115 may subsequently be employed to fill the space between the chip 100 and the substrate 108 to protect solder bump 122 from premature failure due to bump cracks from thermal stresses.

In the preceding detailed description, the present invention is described with reference to specifically exemplary embodiments thereof. It will, however, be evident that various modifications, processes, structures, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method for forming a semiconductor package, comprising:
providing a semiconductor substrate having at least one bump pad formed thereon;
providing a solder mask layer above the bump pad, the solder mask layer having at least one opening formed therein exposing a portion of the bump pad;
forming a layer of solder wettable material on the exposed surface of the bump pad and the sidewalls and substantially the comers of the solder mask layer;
depositing a solder material above the layer of solder wettable material and portions of the solder mask layer; and
reflowing the solder material to create a solder bump.

2. The method of claim 1, wherein the substrate comprises SMD (Solder Mask Define) bump pad design.

3. The method of claim 1, wherein the solder wettable material is a material selected from the group consisting of Cu, Ni, Pd, Co, Pt, Ru, Sn, Ag, Au, and combinations thereof.

4. The method of claim 1, wherein the layer of solder wettable material comprises a Cu/Ni alloy or Ni/Au alloy.

5. The method of claim 1, wherein the layer of solder wettable material is formed by plating or electroless-plating.

6. The method of claim 1, wherein the layer of solder wettable material is formed by sputtering.

7. The method of claim 1, wherein the layer of solder wettable material has a thickness in the range of about 0.1 μm to about 15 μm.

8. A method for forming a semiconductor package substrate, comprising:
providing a semiconductor substrate having at least one bump pad formed thereon;
providing a solder mask layer above the bump pad, the solder mask layer having at least one opening formed therein exposing a portion of the bump pad;
forming a layer of solder wettable material on the exposed surface of the bump pad and the sidewalls and substantially the comers of the solder mask layer;
depositing a solder material above the layer of solder wettable material and portions of the solder mask layer; and
reflowing the solder material to create a solder ball.

9. The method of claim 8, wherein the substrate comprises SMD (Solder Mask Define) bump pad design.

10. The method of claim 8, wherein the solder wettable material is a material selected from the group consisting of Cu, Ni, Pd, Co, Pt, Ru, Sn, Ag, Au, and combinations thereof.

11. The method of claim 8, wherein the layer of solder wettable material comprises a Cu/Ni alloy or Ni/Au alloy.

12. The method of claim 8, wherein the layer of solder wettable material is formed by plating or electroless-plating.

13. The method of claim 8, wherein the layer of solder wettable material is formed by sputtering.

14. The method of claim 8, wherein the layer of solder wettable material has a thickness in the range of about 0.1 μm to about 15 μm.

15. A semiconductor package structure, comprising:
a substrate comprising a bump pad, a solder mask layer formed above the bump pad, the solder mask layer having at least one opening formed therein exposing a portion of the bump pad, and a patterned layer of solder wettable material formed on the exposed surface of the bump pad and on the sidewalls and substantially the comers of the solder mask layer;
a chip having at least an active surface; and
a solder bump disposed on the active surface of the chip and above the layer of solder wettable material of the substrate.

16. The semiconductor package structure of claim 15, further comprising an underfill material filling a space between the chip and the substrate.

17. The semiconductor package structure of claim 15, wherein the substrate comprises SMD (Solder Mask Define) bump pad design.

18. The semiconductor package structure of claim 15, wherein the solder wettable material is a material selected from the group consisting of Cu, Ni, Pd, Co, Pt, Ru, Sn, Ag, Au, and combinations thereof.

19. The semiconductor package structure of claim 15, wherein the layer of solder wettable material comprises a Cu/Ni alloy or Ni/Au alloy.

20. The semiconductor package of claim 15, wherein the layer of solder wettable material has a thickness in the range of about 0.1 μm to about 15 μm.
